(19) United States
(12) Patent Application Publication
(10) Pub. No.: US 2026/0164664 A1
(43) Pub. Date: Jun. 11, 2026

(54) SEMICONDUCTOR MEMORY DEVICE FOR IMPROVING MEMORY INTEGRATION

(71) Applicant: SEOUL NATIONAL UNIVERSITY R&DB FOUNDATION, Seoul (KR)

(72) Inventors: Woo Young CHOI, Seoul (KR); Jin Ho CHANG, Seoul (KR)

(21) Appl. No.: 19/409,559

(22) Filed: Dec. 4, 2025

(30) Foreign Application Priority Data
Dec. 5, 2024 (KR) 10-2024-0179233

(51) Int. Cl. H10B 43/35; H10B 43/27

(52) U.S. Cl. CPC H10B 43/35; H10B 43/27

(57) ABSTRACT

A semiconductor memory device may include a back gate electrode, a gate electrode formed on the back gate electrode, a channel layer formed between the gate electrode and the back gate electrode, a charge storage layer formed between the channel layer and the gate electrode, and a ferroelectric layer formed between the back gate electrode and the channel layer.

### CROSS-REFERENCE TO RELATED APPLICATION

This application claims priority to and the benefit of Korean Patent Application No. 10-2024-0179233, filed on Dec. 5, 2024, which is hereby incorporated by reference for all purposes as if fully set forth herein.

### BACKGROUND

### Field

Embodiments of the invention relate to a semiconductor memory device for improving memory integration.

### Discussion of the Background

A vertical NAND flash memory is a type of flash memory that implements high integration by vertically stacking memory cells. Unlike the conventional planar NAND flash memory, the vertical NAND flash memory can store more data in the same area by stacking cells vertically. This technology marked a significant turning point in data storage technology.

FIG. 1 is a diagram for describing the configuration of a conventional vertical NAND flash memory device. Referring to FIG. 1, the conventional vertical NAND flash memory operates to inject electrons into a charge storage layer (charge trap nitride) and shift a threshold voltage Vₜₕ. That is, during a program process, a high voltage is applied to a gate, electrons penetrate a silicon oxide layer (tunneling oxide) and are trapped in the charge storage layer, and the electrons are discharged to initialize a cell during an erase process. This method has been widely used in a non-volatile memory and has many advantages in terms of reliability and performance.

Thereafter, the vertical NAND flash memory technology has developed in two major directions. First, reducing the physical size of a memory cell; and second, increasing the number of bits stored in a unit cell. Reducing the size of the device increases space efficiency, and increasing the number of bits results in larger storage capacity. These advancements have greatly improved memory density, allowing more data to be stored. However, attempts to make devices smaller and expand an operating voltage range have increased the voltage required for programming and erasing, which has led to problems such as high power consumption and rapid degradation of the device.

Meanwhile, ferroelectric-based vertical NAND flash memory technology was introduced to overcome the limitations of existing electronic storage technology. A ferroelectric memory can operate at a low voltage, offering the potential of reducing power consumption and extending device lifetime. However, the ferroelectric-based vertical NAND flash memory has not been able to improve memory density compared to the conventional electronic storage vertical NAND flash memory and has limitations of not resolving a disturbance problem in a ferroelectric layer and a memory state distribution problem.

The above information disclosed in this Background section is only for understanding of the background of the inventive concepts, and, therefore, it may contain information that does not constitute prior art.

### SUMMARY

Embodiments of the invention are capable of providing a semiconductor memory device for improving memory integration.

Additional features of the inventive concepts will be set forth in the description which follows, and in part will be apparent from the description, or may be learned by practice of the inventive concepts.

According to the present application, a semiconductor memory device for improving memory integration is provided. The semiconductor memory device may include a back gate electrode, a gate electrode formed on the back gate electrode, a channel layer formed between the gate electrode and the back gate electrode, a charge storage layer formed between the channel layer and the gate electrode, and a ferroelectric layer formed between the back gate electrode and the channel layer.

In addition, the semiconductor memory device may further include a first memory region in which the charge storage layer is used, and a second memory region in which the ferroelectric layer is used.

In addition, each of the first memory region and the second memory region may store data independently.

In addition, each of the charge storage layer and the ferroelectric layer may operate independently so that at least four memory states may be implemented in a memory cell.

In addition, the electrical characteristics of the channel layer change during a process of programming and erasing the ferroelectric layer changes so that different memory states are implemented.

In addition, a polarity of the ferroelectric layer changes by a voltage applied through the back gate electrode to control a subthreshold swing SS of the channel layer.

In addition, at least four memory states may be implemented in the memory cell according to a shift of the threshold voltage due to electron storage of the charge storage layer and a state change of a subthreshold swing of the channel layer due to a polarity change of the ferroelectric layer.

In addition, the back gate electrode, the ferroelectric layer, the channel layer, and the charge storage layer can extend in a first direction in parallel, and the back gate electrode has a pillar shape extending in the first direction, and the ferroelectric layer, the channel layer, and the charge storage layer can be configured to surround the back gate electrode.

In addition, the semiconductor memory device can further include a word line connected to the gate electrode, a bit line connected to the channel layer, and a back gate line connected to the back gate electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

The application contains at least one drawing executed in color. Copies of this patent or patent application publication with color drawing will be provided by the Office upon request and payment of the necessary fee.

FIG. 1 is a diagram for describing the configuration of a conventional vertical NAND flash memory device.

FIG. 2 is a vertical cross-sectional view of the configuration of a semiconductor memory device for improving memory integration according to an embodiment of the present application;

FIG. 3 is a color perspective diagram for describing the configuration of a semiconductor memory device for improving memory integration according to an embodiment of the present application.

FIG. 4 is a horizontal cross-sectional view of the configuration of a semiconductor memory device for improving memory integration according to an embodiment of the present application.

FIGS. 5A and 5B are diagrams for describing the configuration and operation of a memory cell of the semiconductor memory device for improving memory integration according to an embodiment of the present application;

FIGS. 6A, 6B, and 6C are diagrams for describing the operation of the semiconductor memory device for improving memory integration according to an embodiment of the present application;

FIG. 7 is a diagram for describing program and erase operations of the semiconductor memory device for improving memory integration according to an embodiment of the present application.

FIGS. 8A, 8B, 8C, and 8D are diagrams for describing a method for manufacturing the semiconductor memory device for improving memory integration according to an embodiment of the present application.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

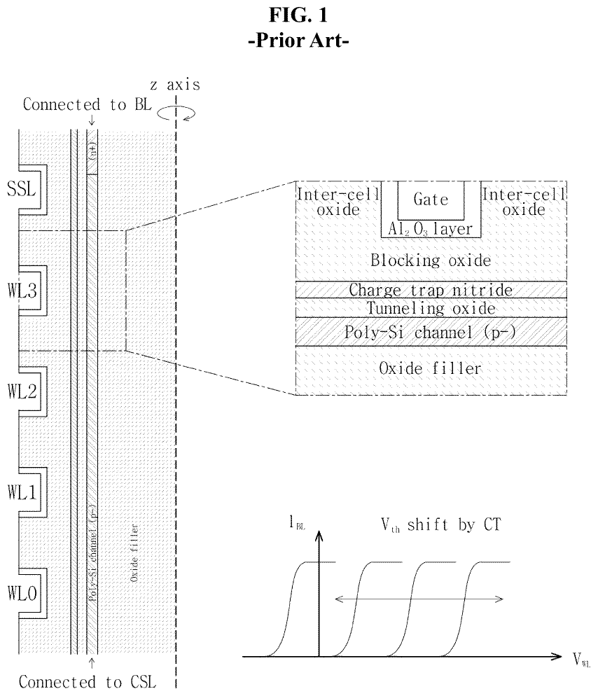

FIG. 1 is a diagram illustrating the configuration of a vertical NAND flash memory device.

Referring to FIG. 1, a conventional vertical NAND flash memory operates to inject electrons into a charge storage layer (charge trap nitride) and shift a threshold voltage Vₜₕ. That is, during a program process, a high voltage is applied to a gate, electrons penetrate a silicon oxide layer (tunneling oxide) and are trapped in the charge storage layer, and the electrons are discharged to initialize a cell during an erase process.

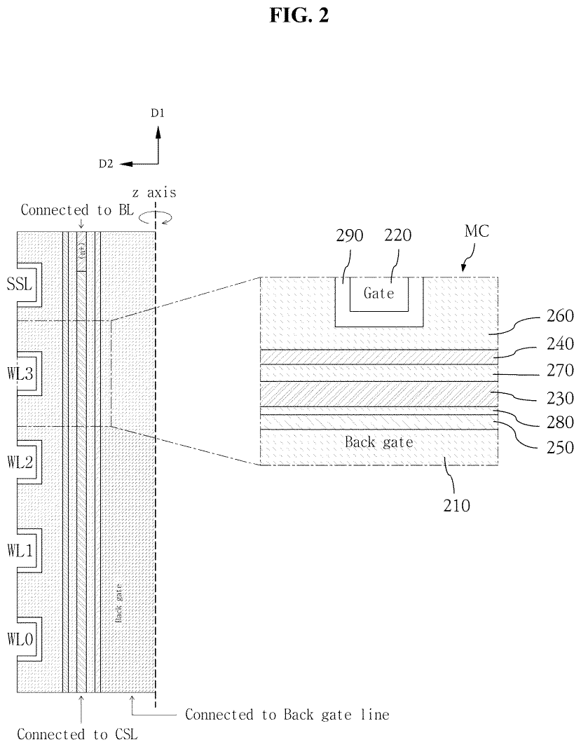

FIGS. 2 to 4 are diagrams for describing the configuration of a semiconductor memory device for improving memory integration according to an embodiment of the present application.

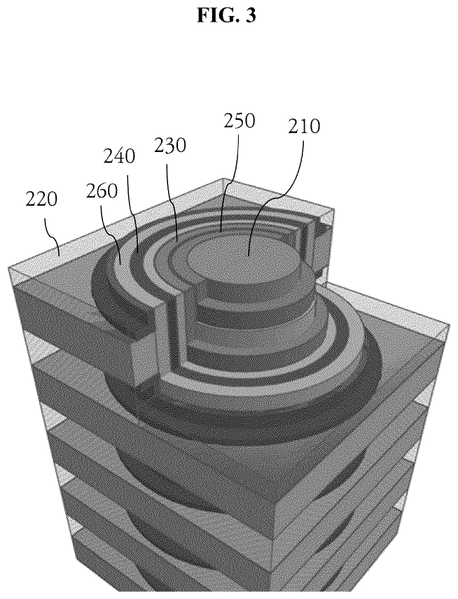

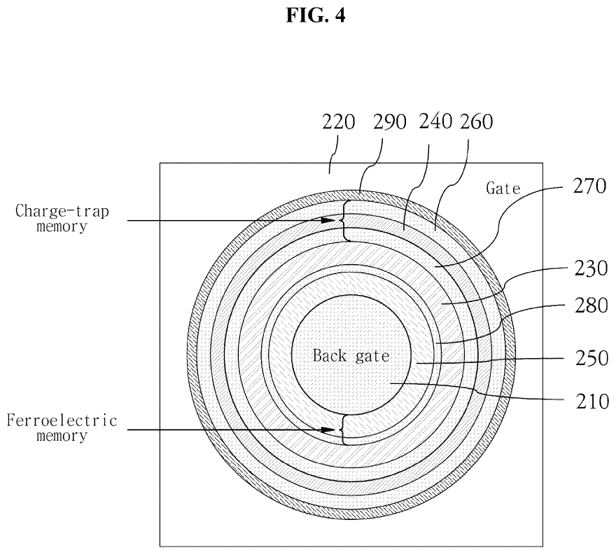

Specifically, FIG. 2 shows a vertical cross-section of the semiconductor memory device, FIG. 3 shows a three-dimensional structure of the semiconductor memory device, and FIG. 4 shows a horizontal cross-section of the semiconductor memory device.

Referring to FIGS. 2 to 4, the semiconductor memory device may include a back gate electrode 210, a gate electrode 220, a channel layer 230, a charge storage layer 240, a ferroelectric layer 250, a blocking oxide layer 260, a tunneling oxide layer 270, and a back oxide layer 280.

In the embodiment, the semiconductor memory device may be formed in a vertical structure. For example, the back gate electrode 210 may have a pillar shape extending in a first direction (vertical direction), and the remaining layers and the gate electrode 220 may be sequentially stacked in a second direction (D2 direction) perpendicular to the first direction (D1 or z-axis direction) to form a vertical structure that surrounds the outside of the back gate electrode 210.

In the embodiment, the semiconductor memory device may include a plurality of memory cells MC connected in series. The gate electrode 220 of each memory cell MC may be connected to a word line WL, and the back gate electrode 210 may be connected to a back gate line BG. A bit line BL may be connected to a drain electrode formed in the channel layer 230, and a common source line CSL may be connected to a source electrode.

The back gate electrode 210 is connected to the back gate line BG, and the ferroelectric layer 250 may be programmed or erased by changing a polarity of the ferroelectric layer 250 by an applied voltage. In the embodiment, the back gate electrode 210 may have a pillar shape extending in the first direction (D1 direction). In addition, in the embodiment, the back gate electrode 210 may have a U-shaped cross-section and an interior of the back gate electrode 210 may be filled with an insulating material.

The back gate electrode 210 may include at least one selected from metals (e.g., tungsten, copper, aluminum, etc.), semiconductors (e.g., silicon and the like), conductive metal nitrides (e.g., titanium nitride, tantalum nitride, etc.), or transition metals (e.g., titanium, tantalum, etc.), without being limited thereto.

The gate electrode 220 is provided on the back gate electrode 210 and connected to the word line WL so that the charge storage layer 240 may be programmed or erased by storing or removing electrons in the charge storage layer 240 by an applied voltage. The gate electrode 220 may be provided in each memory cell MC. The gate electrode 220 may include at least one selected from metals (e.g., tungsten, copper, aluminum, etc.), semiconductors (e.g., silicon and the like), conductive metal nitrides (e.g., titanium nitride, tantalum nitride, etc.), or transition metals (e.g., titanium, tantalum, etc.), without being limited thereto.

The channel layer 230 is disposed between the back gate electrode 210 and the gate electrode 220 and may be formed to surround the outside of the ferroelectric layer 250. The channel layer 230 may include a semiconductor material such as silicon (Si), germanium (Ge), or a mixture thereof, without being limited thereto. The channel layer 230 including a semiconductor material may be used as a channel (i.e., a passage) through which electrons move in the memory cell MC. A portion of a sidewall of the channel layer 230 may be connected to the common source line CSL, and another portion thereof may be connected to the bit line BL.

The channel layer 230 interacts with the ferroelectric layer 250, and thus electrical characteristics may change according to a change in polarity of the ferroelectric layer 250. That is, as the polarity of the ferroelectric layer 250 changes by the voltage applied through the back gate electrode 210, the subthreshold swing SS of the channel layer 230 may change. According to the present application, an independent memory state may be implemented by utilizing a state change of the subthreshold swing SS.

The charge storage layer 240 is disposed between the channel layer 230 and the gate electrode 220 and may be programmed or erased to store (trap) or remove electrons according to the voltage applied to the gate electrode 220. The charge storage layer 240 may implement a plurality of memory states by shifting the threshold voltage Vth during the program and erase processes. For example, the charge storage layer 240 may store binary data such as 0 or 1 through the shifting of the threshold voltage Vth. In addition, in the embodiment, the charge storage layer 240 may be implemented to store more states in a single memory cell MC, such as a triple-level cell (TLC) or quad-level cell (QLC), using a finer difference in threshold voltage.

The ferroelectric layer (Fe layer) 250 may be formed between the back gate electrode 210 and the channel layer 230 to surround a sidewall of the back gate electrode 210. Although the ferroelectric layer 250 is shown as being formed as a single film in the drawing, depending on the embodiment, the ferroelectric layer 250 may include a plurality of ferroelectric layers.

The polarity of the ferroelectric layer 250 changes according to a voltage difference between a channel region and the back gate electrode 210 so that a state of the subthreshold swing SS of the channel layer 230 may be controlled. Specifically, when a predetermined voltage is applied to the back gate electrode 210 to program the ferroelectric layer 250, the polarity of the ferroelectric layer 250 changes in a direction that applies a positive electric field to the channel layer 230 so that the subthreshold swing SS of the channel layer 230 decreases. Conversely, when the ferroelectric layer 250 is erased, the polarity of the ferroelectric layer 250 changes in an opposite direction so that the subthreshold swing SS of the channel layer 230 increases.

The ferroelectric layer 250 may include a ferroelectric material that has polarization characteristics (i.e., its polarity changes) due to an electric field. In the embodiment, the ferroelectric material may be made of a dielectric material containing hafnium. For example, the ferroelectric layer 250 may include HfO₂, HfSiO₂(Si-doped HfO₂), HfAlO₂(Al-doped HfO₂), HfSiON, HfZnO, HfZrO₂, ZrO₂, ZrSiO₂, HfZrSiO₂, ZrSiON, LaAlO, HfDyO₂, or HfScO₂, but the present application is not limited thereto.

The blocking oxide layer (blocking oxide) 260 is formed between the charge storage layer 240 and the gate electrode 220 and may provide electrical insulation therebetween. In this way, electrons trapped in the charge storage layer 240 may be restricted from leaking to the gate electrode 220.

The tunneling oxide layer (tunneling oxide) 270 is formed between the channel layer 230 and the charge storage layer 240 and may provide a tunneling path for electrons to move from the channel layer 230 to the charge storage layer 240.

The back oxide layer (back oxide) 280 is formed between the ferroelectric layer 250 and the channel layer 230 and may provide electrical insulation therebetween. Specifically, the back oxide layer 280 maintains operating reliability of the device by preventing an electric field generated in the ferroelectric layer 250 from directly affecting the channel layer 230, and when the ferroelectric layer 250 controls the subthreshold swing through a polarity change, the back oxide layer 280 may also limits current leakage into the ferroelectric layer.

The blocking oxide layer 260, the tunneling oxide layer 270, and the back oxide layer 280 may each be made of silicon oxide (SiO₂), without being limited thereto.

In addition, in the embodiment, a gate insulating layer 290 may be formed between the blocking oxide layer 260 and the gate electrode 220. The gate insulating layer 290 may be made of aluminum oxide (Al₂O₃) having high permittivity and insulating characteristics, without being limited thereto.

In the embodiment, the semiconductor memory device may further include an intercell oxide layer for insulation between the memory cells MC. The intercell oxide layer may assist each memory cell MC to operate independently and prevent electrical interference between the memory cells MC, thereby increasing the reliability of data storage.

In the embodiment, each of the memory cells MC of the semiconductor memory device may include a first memory region (charge-trap memory) and a second memory region (ferroelectric memory). The first memory region and the second memory region may independently store data using the charge storage layer 240 and the ferroelectric layer 250, respectively. For example, the first memory region is implemented as an oxide-nitride-oxide (ONO) layer including the blocking oxide layer 260, the charge storage layer 240, and the tunneling oxide layer 270 and may store data through a threshold voltage shift due to electron trapping and removal of the charge storage layer 240 according to voltage application to the gate electrode 220. In addition, for example, the second memory region is implemented through the ferroelectric layer 250 and the back oxide layer 280 and may store data through a state change of the subthreshold swing SS (increase or decrease) according to a change in polarity of the ferroelectric layer 250 when a voltage is applied to the back gate electrode 210.

In the embodiment, the semiconductor memory device may implement at least four memory states per memory cell MC according to a threshold voltage shift due to electron storage of the charge storage layer 240 and a state change of the subthreshold swing SS due to a change in polarity of the ferroelectric layer 250.

An example of the configuration of the semiconductor memory device is shown in FIGS. 2 to 4, and various configurations may be applied according to embodiments of the present application.

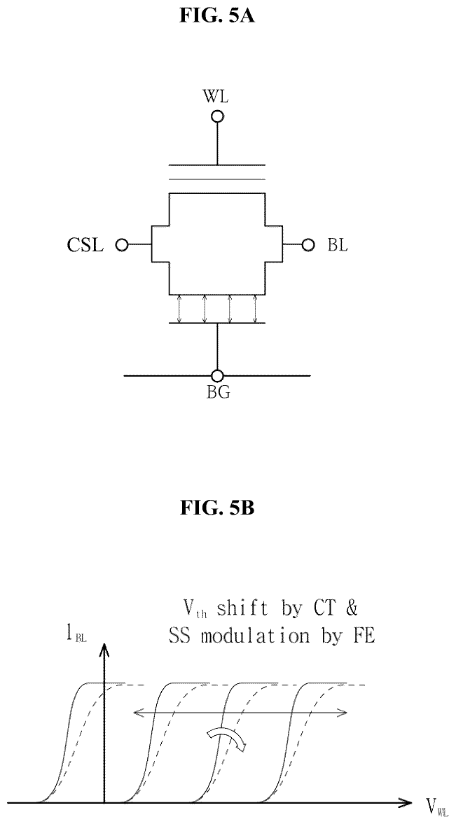

FIGS. 5A and 5B are diagrams for describing the configuration and operation of a memory cell of the semiconductor memory device for improving memory integration according to an embodiment of the present application.

Referring to FIG. 5A, the semiconductor memory device may include a plurality of memory cells MC. As shown in the circuit diagram of FIG. 5A, the gate electrode 220 of each memory cell MC may be connected to a word line WL, and the back gate electrode 210 may be connected to a back gate line BG. The bit line BL may be connected to a drain electrode formed in the channel layer 230, and the common source line CSL may be connected to a source electrode.

The memory cell MC may perform program and/or erase operations on the ferroelectric layer 250 by a voltage difference between the channel region and the back gate electrode 210 and may perform program and/or erase operations on the charge storage layer 240 by a voltage difference between the channel region and the gate electrode 220.

Referring to FIG. 5B, program and/or erase operations are independently performed on the charge storage layer 240 and the ferroelectric layer 250 so that memory integration may be improved compared to memory devices using conventional electronic storage methods through the threshold voltage shift and control (state change) of the subthreshold swing SS.

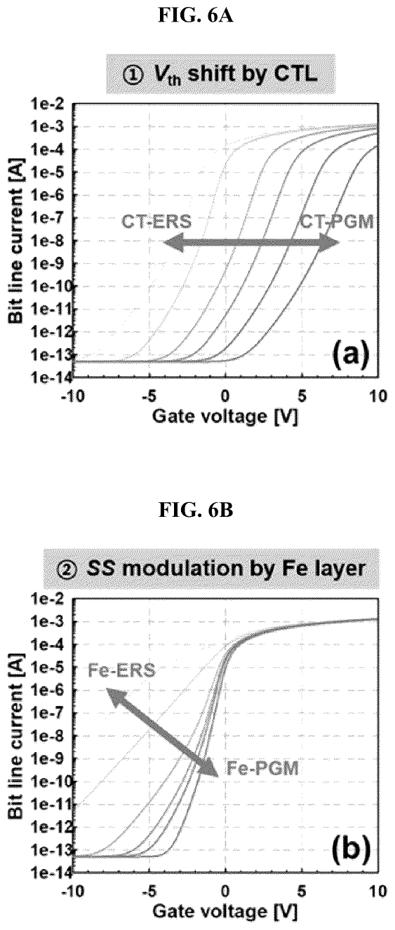

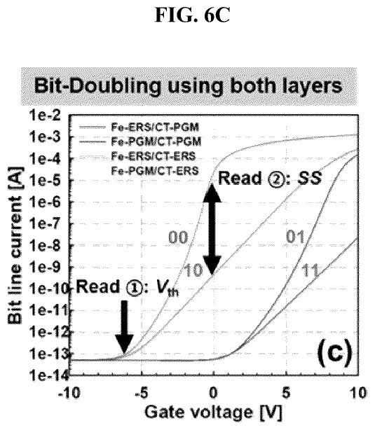

FIGS. 6A to 6C are diagrams for describing the operation of the semiconductor memory device for improving memory integration according to the embodiment of the present application.

Referring to FIGS. 6A to 6C, different states in which the charge storage layer 240 and the ferroelectric layer 250 in the memory cells MC of the semiconductor memory device are implemented in a manner of operating individually and in a manner of operating together can be observed.

When only the charge storage layer 240 operates, as shown in FIG. 6A, when programming is performed in the same manner as in the conventional memory, electrons are stored to shift the threshold voltage Vth to the right, and when erasing is performed, electrons are released to shift the threshold voltage Vth to the left.

When only the ferroelectric layer 250 operates, as shown in FIG. 6B, when programming is performed, the polarity changes in a direction of providing a positive electric field to the channel layer 230, thus decreasing the subthreshold swing SS, and when erasing is performed, the polarity changes in an opposite direction, thus increasing the subthreshold swing SS.

On the other hand, in the semiconductor memory device according to the present application, the charge storage layer 240 and the ferroelectric layer 250 operate together, but function independently of each other. Therefore, as shown in FIG. 6C, when each of the charge storage layer 240 and the ferroelectric layer 250 stores two states, a total of four different memory states can be stored.

Meanwhile, in order to check the subthreshold swing SS change of the ferroelectric layer 250 through a read operation, unlike the conventional method, an additional read process may be required for reading the subthreshold swing SS by slightly increasing a read voltage after reading the threshold voltage.

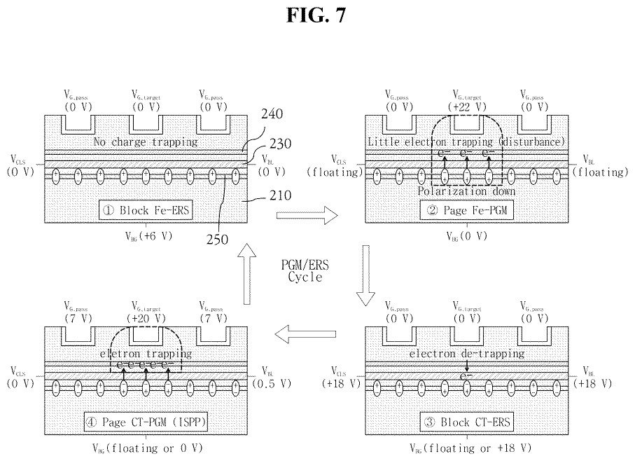

FIG. 7 is a diagram for describing the program and erase operations of the semiconductor memory device for improving memory integration according to an embodiment of the present application.

Referring to FIG. 7, the programming may be performed after erasing the ferroelectric layer 250 first. This is because, when programming is performed on the ferroelectric layer 250, there is a probability that charges may also flow into the charge storage layer 240. The erase operation of the ferroelectric layer 250 is performed in block units, and during this process, a positive voltage is applied to the back gate electrode 210 and the channel layer 230 is set to ground. Thereafter, the program is performed in page units. In this case, data is recorded by applying a voltage to the gate electrode 220 and back gate electrode 210 while maintaining the channel layer 230 in a floating state.

Subsequently, the erase and program operations are performed on the charge storage layer 240. The erasing and programming of the charge storage layer 240 are performed in the same manner as in the conventional vertical NAND flash memory. The erasing is performed in block units, and the programming is performed in page units. In this case, in order for the data of the ferroelectric layer 250 not to change while manipulating the charge storage layer, the back gate electrode 210 may be controlled to maintain the same voltage as the channel layer 230.

According to the present application, independent manipulation of the charge storage layer 240 and the ferroelectric layer 250 is possible through these program and erase operations, and interference between layers is minimized so that the performance and stability of a high-density memory device can be improved.

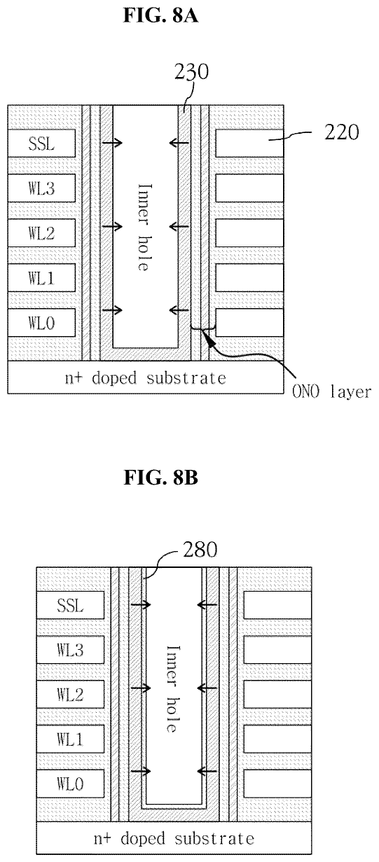

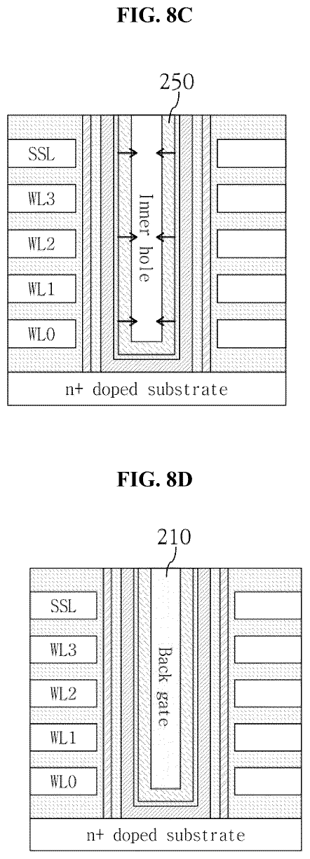

FIGS. 8A to 8D are diagrams for describing a method for manufacturing the semiconductor memory device for improving memory integration according to an embodiment of the present application.

In FIGS. 8A to 8D, a five-stage word line WL is shown, but the same process method may be applied to a semiconductor memory device with a higher number of stages.

First, referring to FIGS. 8A and 8B, the manufacturing method may include the same processes as the manufacturing method of the existing vertical NAND flash memory up to the formation of the channel layer 230. That is, like the existing vertical NAND flash memory, the polysilicon channel layer 230 may be formed after forming the gate electrode 220 and the ONO layer. However, as shown in FIG. 8B, when depositing SiO₂ into the interior of the channel layer 230, there is a difference in that the oxide layer is formed by depositing only a thin thickness rather than filling the interior completely, and then proceeding to the next process.

Next, referring to FIGS. 8C and 8D, the ferroelectric layer 250 is deposited into a cavity inside the oxide layer, and the interior of the ferroelectric layer 250 is filled with a metal and/or polysilicon to form the back gate electrode 210 so that a semiconductor memory device to which the ferroelectric layer 250 and the back gate electrode 210 are added may be manufactured.

Meanwhile, although not shown in the drawings, the manufacturing method may further include a process of etching the substrate at a lower end portion. In this way, a structure in which the back gate electrode 210 passes through the substrate and is connected to a line at the lower end portion can be formed.

According to the present application, since the existing vertical NAND flash memory process is used without modification, and additional processes for forming the ferroelectric layer and the back gate also utilize existing process technologies, it is possible to implement a device with a high degree of technological perfection that stably improves memory integration.

According to embodiments of the present application, two independent memory storage methods can be implemented through a charge storage layer and a ferroelectric layer which operate independently of each other, and more data can be stored efficiently.

In addition, according to the embodiments of the present application, since the existing vertical NAND flash memory process is used without modification, and additional processes for forming a ferroelectric layer and a back gate also utilize existing process technologies, it is possible to implement a device with a high degree of technological perfection that stably improves memory integration.

In addition, according to the embodiments of the present application, since a back gate electrode used for programming/erasing the ferroelectric layer and a gate electrode used for reading the ferroelectric layer are used separately, a disturbance phenomenon that can occur during the process of programming and erasing the ferroelectric layer can be reduced.

In addition, according to the embodiments of the present application, by controlling a subthreshold swing using the ferroelectric layer, the power efficiency of a memory device can be improved and stable operation is possible even at a low voltage.

In addition, according to the embodiments of the present application, it is compatible with existing triple-level cell (TLC) and quad-level cell (QLC) technologies, thereby enabling implementation of a high-density and large-capacity memory.

The effects obtained by the embodiments of the present application are not limited to the above-mentioned effects and other effects which are not mentioned can be clearly understood by those skilled in the art to which the present application pertains from the above description.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A semiconductor memory device comprising:
a back gate electrode;
a gate electrode formed on the back gate electrode;
a channel layer formed between the gate electrode and the back gate electrode;
a charge storage layer formed between the channel layer and the gate electrode; and
a ferroelectric layer formed between the back gate electrode and the channel layer.

2. The semiconductor memory device of claim 1, further comprising:
a first memory region in which the charge storage layer is used; and
a second memory region in which the ferroelectric layer is used.

3. The semiconductor memory device of claim 2, wherein each of the first memory region and the second memory region store data independently.

4. The semiconductor memory device of claim 1, wherein each of the charge storage layer and the ferroelectric layer operate independently so that at least four memory states are implemented in a memory cell.

5. The semiconductor memory device of claim 4, wherein the electrical characteristics of the channel layer change during a process of programming and erasing the ferroelectric layer so that different memory states are implemented.

6. The semiconductor memory device of claim 5, wherein a polarity of the ferroelectric layer changes by a voltage applied through the back gate electrode to control a subthreshold swing (SS) of the channel layer.

7. The semiconductor memory device of claim 4, wherein the at least four memory states are implemented in the memory cell according to a shift of a threshold voltage due to electron storage of the charge storage layer and a state change of a subthreshold swing of the channel layer due to a polarity change of the ferroelectric layer.

8. The semiconductor memory device of claim 1,
wherein the back gate electrode, the ferroelectric layer, the channel layer, and the charge storage layer extend in a first direction in parallel; and
wherein the back gate electrode has a pillar shape extending in the first direction, and
wherein the ferroelectric layer, the channel layer, and the charge storage layer are configured to surround the back gate electrode.

9. The semiconductor memory device of claim 1, further comprising:
a word line connected to the gate electrode;
a bit line connected to the channel layer; and
a back gate line connected to the back gate electrode.
